(19) United States
(12) Patent Application Publication
(10) Pub. No.: US 2026/0353902 A1
(43) Pub. Date: Nov. 5, 2026

(54) DISPLAY PANEL AND PREPARATION METHOD THEREOF

(71) Applicant: WUHAN CHINA STAR OPTOELECTRONICS TECHNOLOGY CO., LTD., Wuhan, Hubei (CN)

(72) Inventors: Qian LIU, Wuhan, Hubei (CN); Zuojia WANG, Wuhan, Hubei (CN); Xiaomin WU, Wuhan, Hubei (CN); Jiajie WANG, Wuhan, Hubei (CN); Peng HE, Wuhan, Hubei (CN)

(73) Assignee: WUHAN CHINA STAR OPTOELECTRONICS TECHNOLOGY CO., LTD., Wuhan, Hubei (CN)

(21) Appl. No.: 18/994,504

(22) PCT Filed: Nov. 29, 2023
(86) PCT No.: PCT/CN2023/135072

§ 371 Date: Jan. 14, 2025

(30) Foreign Application Priority Data
Sep. 26, 2023 (CN) 202311264650.2

(51) Int. Cl. H10H 29/85; H10H 29/01; H10H 29/34; H10H 29/49; H10H 29/853

(52) U.S. Cl. CPC H10H 29/8581; H10H 29/012; H10H 29/0365; H10H 29/34; H10H 29/49; H10H 29/853

(57) ABSTRACT

The present application provides a display panel and a preparation method thereof; in the display panel, by making an orthographic projection area of the heat dissipation surface of the metal heat conductive layer away from the driving circuit layer larger than the orthographic projection area of the connection surface in direct contact with the driving circuit layer, and disposing the connection surface corresponding to the wiring region, the metal heat conductive layer can be made in direct contact with the driving circuit layer in the wiring region, the glass substrate can be replaced with the metal heat conductive layer without increasing the thickness of the display panel, and the heat dissipation effect can be improved.

### TECHNICAL FIELD

The present application relates to the field of display technology, and in particular, to a display panel and a preparation method thereof.

### BACKGROUND ART

Micro-LED (micro light-emitting diode) display devices are widely used due to their advantages such as self-illumination, high brightness, high contrast, high resolution and colour saturation, long lifespan, fast response speed, and low power consumption. Since a photoelectric conversion rate of Micro-LED is only about 30%, a large amount of power consumption is converted into heat, resulting in a high temperature of the Micro-LED devices. In order to make the Micro-LED display devices work normally, the heat from the Micro-LED devices will be dissipated out via the manners such as heat conduction, thermal radiation, convection. However, during actual use, it was found that a glass substrate has a poor heat conductivity, such that it is difficult for the heat of the Micro-LED devices to be conducted out through the glass, resulting in the higher temperature of the Micro-LED display devices, failure to normal use and the shortened lifespan of the Micro-LED display devices, and as the display devices develop toward high resolution and high brightness, the number of light-emitting chips will be increased, further increasing heat, exacerbating the problem of poor display of the Micro-LED display devices, and reducing the lifespan of the Micro-LED display devices.

Therefore, the existing Micro-LED display devices have a problem that the poor heat dissipation performance of the glass substrate causes poor display of the Micro-LED display devices.

### SUMMARY

### Technical Problem

Embodiments of the present application provide a display panel and a preparation method thereof to alleviate the problem of the existing Micro-LED display devices that the poor heat dissipation performance of the glass substrate causes poor display of the Micro-LED display devices.

### Technical Solutions

In order to solve the above problem, the technical solutions provided by the present application are as follows:

An embodiment of the present application provides a display panel, which includes:
a metal heat conductive layer;
an organic layer, provided on a side of the metal heat conductive layer;
a driving circuit layer, provided on a side of the organic layer away from the metal heat conductive layer, where the driving circuit layer includes a thin film transistor and a metal wiring;
a display layer, provided on a side of the driving circuit layer away from the organic layer, and controllably connected to the driving circuit layer;
the display panel includes a wiring region and a non-wiring region, and at least one of the thin film transistor and the metal wiring is provided in the wiring region; the metal heat conductive layer includes a connection surface close to the driving circuit layer and in direct contact with the driving circuit layer, and a heat dissipation surface away from the driving circuit layer, in an orthographic projection direction of the display panel, an orthographic projection area of the heat dissipation surface is larger than an orthographic projection area of the connection surface, the connection surface is disposed corresponding to the wiring region.

Meanwhile, embodiments of the present application provide a preparation method for a display panel. The display panel as described in any one of the above embodiments above is prepared by the preparation method for the display panel. The preparation method for the display panel includes:
Providing substrate;
Forming a peeling layer on the substrate;
Forming a metal heat conductive layer and an organic layer on the peeling layer, and etching the metal heat conductive layer;
Forming a driving circuit layer and a display layer sequentially on the organic layer;
Peeling off the peeling layer and the substrate to obtain the display panel.

### DESCRIPTION OF THE DRAWINGS

The technical solutions and other beneficial effects of the present application will be apparent through a detailed description of the specific embodiments of the present application below in conjunction with the accompanying drawings.

FIG. 1 is a schematic diagram of an existing Micro-LED display device.

FIG. 2 is a schematic diagram of a display panel provided by an embodiment of the present application.

FIG. 3 is a schematic diagram of a heat dissipation process of the test wiring provided by an embodiment of the present application.

FIG. 4 is a flow chart of a preparation method for a display panel provided by an embodiment of the present application.

FIG. 5 is a first structural schematic diagram of a display panel corresponding to each step of the preparation method for a display panel provided by an embodiment of the present application.

FIG. 6 is a second structural schematic diagram of a display panel corresponding to each step of the preparation method for a display panel provided by an embodiment of the present application.

### DESCRIPTION OF THE EMBODIMENTS

The technical solutions in the embodiments of the present application will be clearly and completely described below with reference to the accompanying drawings in the embodiments of the present application. Obviously, the described embodiments are only some of the embodiments of the present application, but not all of the embodiments. Based on the embodiments in the present application, all other embodiments obtained by those skilled in the art without making creative efforts fall within the scope of protection of the present application.

In the description of the present application, it is to be understood that the orientations or positional relationships indicated by the terms “centre”, “longitudinal”, “transversal”, “length”, “width”, “thickness”, “upper”, “lower”, “front”, “back”, “left”, “right”, “vertical”, “horizontal”, “top”, “bottom”, “inner”, “outer”, “clockwise”, “counter clockwise” and the like are the orientations or positional relationships shown based on the drawings. They are only for the convenience of describing the present application and simplifying the description, without indicating or implying that the referred device or element must have a specific orientation, are constructed and operated in a specific orientation and therefore should not be construed as limiting the present application. In addition, the terms “first” and “second” are only used for descriptive purpose and cannot be understood as indicating or implying relative importance or implicitly indicating the quantity of the indicated technical features. Therefore, the features defined by “first” and “second” may explicitly or implicitly include one or more of the features. In the description of the present application, “plurality of” means two or more, unless otherwise clearly and specifically limited.

In the description of this application, it should be noted that, unless otherwise clearly specified and limited, the terms “installation”, “connected” and “connection” should be understood in a broad sense. For example, it may either a fixed connection or a detachable connection, or integral connection; it may be a mechanical connection, an electrical connection or a mutual communication; it may be direct connection, or indirect connection through an intermediary, it maybe the internal communication inside two elements or the interaction relationship between two elements. For those of ordinary skill in the art, the specific meanings of the above terms in the present application can be understood according to the specific circumstances.

In the present application, unless otherwise expressly specified and limited, the first feature being “above” or “below” a second feature may include direct contact between the first and second features, or may also include the indirect contact between the first and second features but the contact through additional feature between them. Furthermore, the first feature being “above”, “on” and “over” a second feature includes the first feature being directly above and diagonally above the second feature, or simply mean that a horizontal height of the first feature is higher than that of the second feature. The first feature being “below”, “under” and “below” the second feature includes the first feature being directly below and diagonally below the second feature, or simply means that the horizontal height of the first feature is smaller than that of the second feature.

The following disclosure provides many different embodiments or examples for implementing the various structures of the present application. To simplify the disclosure of the present application, the components and arrangements of specific examples are described below. Of course, they are merely exemplary and are not intended to limit the application. Furthermore, the present application may repeat reference numbers and/or reference letters in different examples, such repetition being for the purposes of simplicity and clarity and does not by itself indicate a relationship between the various embodiments and/or arrangements as discussed. In addition, the present application provides examples of various specific processes and materials, but one of ordinary skill in the art will recognize the application of other processes and/or the use of other materials.

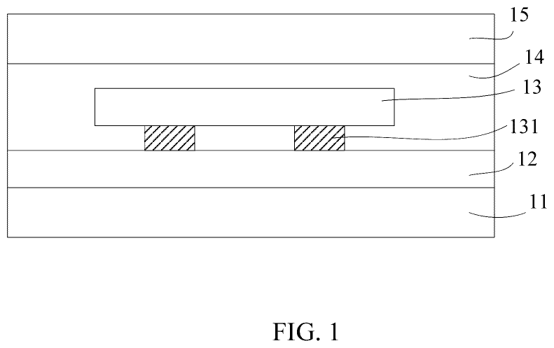

As shown in FIG. 1, the existing Micro-LED display device includes a glass substrate 11, a thin film transistor array layer 12, a light-emitting chip 13, a packaging glue 14 and a glass cover plate 15. The light-emitting chip 13 is connected to the thin film transistor array layer 12 via a solder point 131. During the use of the Micro-LED display device, the photoelectric conversion rate of the light-emitting chip 13 is only 30%, a large amount of power consumption will be converted into heat, and a portion of the heat will be conducted out through the packaging glue 14 and the glass cover plate 15, and the heat conducted to the glass cover plate 15 will be dissipated out through the manner of thermal radiation and convection with the air. A part of the heat will be conducted out through the solder point 131, the thin film transistor array layer 12 and the glass substrate 11, and the heat conducted to the glass substrate 11 will be dissipated out through the manner of heat radiation and convection with the air, thereby avoiding the too high temperature of the light-emitting chip 13, and avoiding the too high temperature of the Micro-LED display device, so that the Micro-LED display device can display normally and have a long lifespan. However, during actual use, it was found that when heat is transmitted to the glass substrate 11, the heat generated by the light-emitting chip 13 is difficult to dissipate from the glass substrate 11 due to the poor heat conductivity of the glass substrate, resulting in a higher temperature of the Micro-LED display device. Moreover, as the display device develops towards high resolution and high brightness, the number of light-emitting chips will be increased, which will further increase heat, causing the problem that the Micro-LED display device fails to display normally and the lifespan is decreased. Therefore, the existing Micro-LED display device has a problem that the poor heat dissipation performance of the glass substrate causes poor display of the Micro-LED display device.

In view of the above technical problem, embodiments of the present application provide a display panel and a preparation method thereof to alleviate the above technical problem.

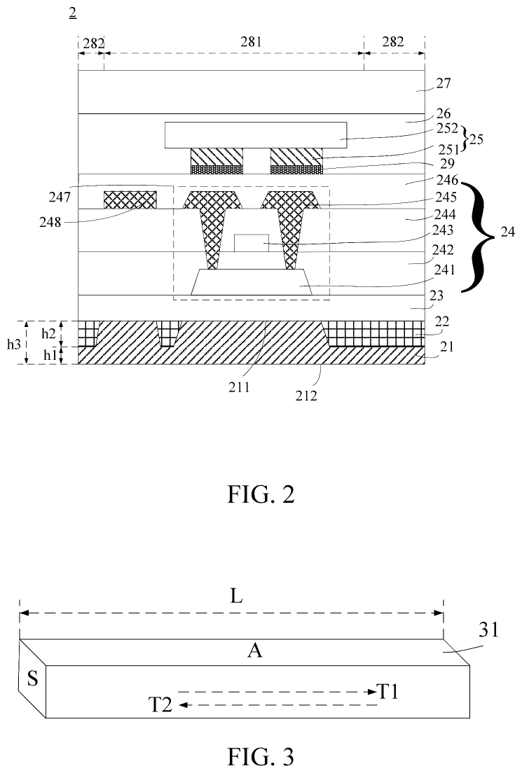

As shown in FIG. 2, an embodiment of the present application provides a display panel. The display panel 2 includes:
a metal heat conductive layer 21;
an organic layer 22, provided on a side of the metal heat conductive layer 21;
a driving circuit layer 24, provided on a side of the organic layer 22 away from the metal heat conductive layer 21, the driving circuit layer 24 includes a thin film transistor 247 and a metal wiring 248;
a display layer 25, provided on a side of the driving circuit layer 24 away from the organic layer 22;

The display panel 2 includes a wiring region 281 and a non-wiring region 282. At least one of the thin film transistor 247 and the metal wiring 248 is provided in the wiring region 281; the metal heat conductive layer 21 includes a connection surface 211 close to the driving circuit layer 24 and in direct contact with the driving circuit layer 24, and a heat dissipation surface 212 away from the driving circuit layer 24, in the orthographic projection direction of the display panel 2 (for example, the horizontal surface direction of the display panel 2 from a top view), the orthographic projection area of the heat dissipation surface 212 is larger than the orthographic projection area of the connection surface 211, and the connection surface 211 is disposed corresponding to the wiring region 281.

Embodiments of the present application provide a display panel, which is provided with a metal heat conductive layer so that the orthogonal projection area of the heat dissipation surface of the metal heat conductive layer away from the driving circuit layer is larger than the orthogonal projection area of the connection surface in direct contact with the driving circuit layer, and the connection surface is disposed corresponding to the wiring region. As such, the metal heat conductive layer can be made in direct contact with the driving circuit layer in the wiring region, so that when the display panel generates heat, the heat can be conducted out through the metal heat conductive layer, and the metal heat conductive layer has a heat conductivity superior to the glass, which can improve the heat dissipation effect of the display panel, and the metal heat conductive layer can replace the glass substrate without increasing the thickness of the display panel. Meanwhile, the heat dissipation surface can conduct heat to the entire surface, further improving the heat dissipation effect.

In some embodiments, the projection of the metal heat conductive layer on the plane where the display layer is located covers the projection of the driving circuit layer on the plane where the display layer is located.

In some embodiments, in a direction perpendicular to the display panel, the thickness of the portion of the metal heat conductive layer located in the wiring region is greater than the thickness of the portion of the metal heat conductive layer located in the non-wiring region. In the non-wiring region, the organic layer is disposed between the metal heat conductive layer and the driving circuit layer.

In some embodiments, a sum of the thickness of the portion of the metal heat conductive layer located in the non-wiring region and the thickness of the organic layer is equal to a sum of the thickness of the portion of the metal heat conductive layer located in the wiring region.

In some embodiments, a thin film transistor is provided in the wiring region, and the portion of the metal heat conductive layer located in the wiring region covers the wiring region corresponding to the thin film transistor.

In some embodiments, a metal wiring is provided in the wiring region, the portion of the metal heat conductive layer located in the wiring region is disposed corresponding to the metal wiring, and the portion of the metal heat conductive layer located in the wiring region covers the projection area of the metal wiring on the display layer.

In some embodiments, the metal wiring is provided in the wiring region, and the metal wiring is electrically connected to the metal heat conductive layer.

In some embodiments, the thickness of the portion of the metal heat conductive layer located in the non-wiring region ranges from one-fiftieth to one-fifth of the thickness of the portion of the metal heat conductive layer located in the wiring region.

In some embodiments, the material of the metal heat conductive layer includes at least one of copper, aluminium, tin.

In some embodiments, the display layer includes a micro light-emitting diode device, the micro light-emitting diode device includes an electrode layer and a light-emitting layer, the display panel further includes a bonding pad, the electrode layer is disposed between the light-emitting layer and the driving circuit layer, the electrode layer is connected to the driving circuit layer through the bonding pad, and the bonding pad of the electrode layer is disposed corresponding to the portion of the metal heat conductive layer located in the wiring region.

In some embodiments, the projection area of the metal heat conductive layer on the plane where the display layer is located covers the projection area of the driving circuit layer on the plane where the display layer is located. By making the projection area of the metal heat conductive layer on the plane where the display layer is located greater than or equal to the projection area of the driving circuit layer on the plane where the display layer is located, the surface area of the metal heat conductive layer can be increased, so that the metal heat conductive layer can be arranged on the entire surface, and when the heat conductive layer dissipates heat through the manner of convection and thermal radiation, it is possible to reduce thermal resistance, improve the heat dissipation performance of the metal heat conductive layer, and improve the heat dissipation effect of the display panel.

Specifically, the area of the metal heat conductive layer in the display panel may be made greater than or equal to the area of any other film layers than the metal heat conductive layer in the display panel, so that the area of the metal heat conductive layer is maximized and the surface area of the metal heat conductive layer is increased to improve the heat dissipation effect of the display panel.

In some embodiments, as shown in FIG. 2, in the direction perpendicular to the display panel 2, the thickness h3 of the portion of the metal heat conductive layer 21 located in the wiring region 281 is greater than the thickness h1 of the portion of the metal heat conductive layer 21 located in the non-wiring region 282. The organic layer 22 is disposed between the metal heat conductive layer 21 and the driving circuit layer 24 in the non-wiring region 282. By providing the metal heat conductive layer such that the thickness of the metal heat conductive layer located in the wiring region is greater than the thickness of the portion of the metal heat conductive layer located in the non-wiring region and the metal heat conductive layer is in direct contact with the driving circuit layer in the wiring region, it is possible to conduct the heat out through the metal heat conductive layer when the display panel generates heat, and the metal heat conductive layer has the heat conductivity superior to that of glass, which can improve the heat dissipation effect of the display panel. The metal heat conductive layer can replace the glass substrate without increasing the thickness of the display panel. Meanwhile, in the non-wiring region, the organic layer is provided between the metal heat conductive layer and the driving circuit layer, such that static electricity will not occur when forming the driving circuit layer, improving the yield rate of the display panel.

Specifically, the driving circuit layer 24 includes a buffer layer 23. In the wiring region 281, the metal heat conductive layer 21 is in direct contact with the buffer layer 23. In the non-wiring region 282, the organic layer 22 is disposed between the metal heat conductive layer 21 and the buffer layer 23. By disposing the organic layer between the metal heat conductive layer and the buffer layer, the static electricity will not occur when forming the buffer layer, thereby improving the yield rate of the display panel.

Specifically, no glass substrate is provided under the metal heat conductive layer to avoid the poor heat conductivity of the glass substrate and failure to dissipate heat through the manners such as conduction, radiation and convection.

Specifically, no other film layers are provided under the metal heat conductive layer to avoid the poor heat conductivity of the other film layers and failure to dissipate heat through the manners such as conduction, radiation and convection. For example, no back plate is provided under the metal heat conductive layer, no support layer is provided under the metal heat conductive layer, and no heat dissipation layer is provided under the metal heat conductive layer, so as to dissipate heat through the metal heat conductive layer, and such that it is possible to reduce the thickness of the display panel and reduce the weight of the display panel.

Specifically, the heat conductivity of the metal heat conductive layer is greater than the heat conductivity of glass.

Specifically, as shown in FIG. 3, a test wiring 31 is taken as an example to illustrate the thermal resistance during the heat dissipation process. As shown in FIG. 3, the length of the test wiring 31 is L, the surface area is A, the cross-sectional area is S, the heat conductivity is C, and the heat conduction direction is transverse, that is, the direction from left to right shown as T1 or from right to left as shown in T2 in FIG. 3, during the heat transfer process, the test wiring 31 will dissipate heat from left to right through thermal conduction, dissipate heat from the upper surface to other objects through thermal radiation, and dissipate heat from the upper surface by convention with air in the convection manner. When the test wiring 31 dissipates heat through thermal conduction, the thermal conduction resistance is the ratio of the length L of the test wiring 31 to the heat conductivity C of the test wiring and the cross-sectional area S of the test wiring. That is, the heat conductivity resistance is L/(C×S), the convection thermal resistance of the test wiring 31 when dissipating heat through convection is the ratio of 1 to the convection heat transfer coefficient K1 and the surface area A of the test wiring 31, that is, the convection thermal resistance is 1/(K1×A), When the test wiring 31 transfers the temperature to an object at a relatively lower-temperature through thermal radiation, the thermal radiation resistance of the test wiring 31 is the ratio of 1 to the radiation heat transfer coefficient K2 and the surface area A of the test wiring 31, then the heat radiation thermal resistance is 1/(K2×A). From the above analysis, it can be seen that the thermal resistance of the test wiring 31 is proportional to its length and inversely proportional to its surface area, cross-sectional area and heat conductivity. Therefore, in order to improve the heat dissipation performance of the test wiring 31, it can be achieved by increasing its surface area, cross-sectional area and heat conductivity. Embodiments of the present application improve the heat dissipation capacity of the display panel by using a metal heat conductive layer to replace the glass substrate, that is, using a material with a larger heat conductivity to replace the glass, and can increase the cross-sectional area of the portion of the heat conductive layer located in the wiring region by making the thickness of the portion of the metal heat conductive layer located in the wiring region greater than that of the metal heat conductive layer located in the non-wiring region to further improve the heat dissipation capacity of the display panel, and can further improve the heat dissipation capacity of the display panel by allowing the metal heat conductive layer to be arranged on the entire surface to increase its surface area.

Specifically, compared with using a glass substrate for heat dissipation, the heat conductivity of the glass substrate is lower, and the size of the light-emitting chip is smaller, such that when the heat of the light-emitting chip is dissipated to the glass substrate, the heat will accumulate in the region of the glass substrate corresponding to the light-emitting chip, the surface area of the actual heat dissipation portion is small, the convection thermal resistance and radiation thermal resistance are large, and the heat dissipation effect is poor. The present application has used the metal for heat dissipation. The heat conductivity of metal is good. When the heat is dissipated to the metal, the heat will be transferred to the entire surface of the metal, which is equivalent to increasing the surface area of the metal for heat dissipation, reducing the convection thermal resistance and radiant heat resistance and improving the heat dissipation effect.

Specifically, compared with the display panel in which other film layers, such as a glass substrate, are provided under the metal heat conductive layer, the embodiments of the present application can reduce the thermal resistance under the display layer by not disposing other film layers under the metal heat conductive layer, thereby improving the heat dissipation effect of the display panel.

Specifically, compared with the display panel that is not provided with other film layers between the metal heat conductive layer and the driving circuit layer, the embodiments of the present application can avoid occurrence of static electricity when the driver circuit layer is formed directly on the metal heat conductive layer to result in poor display by providing an organic layer between the metal heat conductive layer and the driving circuit layer. And compared with a display panel in which the thickness of the metal heat conductive layer on the entire surface is consistent, the thickness of the portion of the metal heat conductive layer located in the wiring region is greater than the thickness of the portion of the metal heat conductive layer located in the non-wiring region in the embodiment of the present application, such that the heat in the wiring region can be transferred and the thickness of the display panel can be reduced.

Specifically, compared with the display panel in which patterned metal is provided in the organic layer, embodiments of the present application provide the heat dissipation surface of the metal heat conductive layer on the entire surface, so that when the heat is transferred through the portion of the metal heat conductive layer located in the wiring region, it can be quickly transferred to the entire surface of the metal heat conductive layer due to the larger heat conductivity of the metal heat conductive layer, improving the heat dissipation effect.

Specifically, the thickness of the portion of the metal heat conductive layer located in the wiring region is made greater than the thickness of the portion of the metal heat conductive layer located in the non-wiring region, so that during the process of heat transfer in the display panel, the thin film transistor and/or wiring conduct heat conduction, which can quickly transfer heat to the metal heat conductive layer, improve the heat conduction efficiency and improve the heat dissipation effect.

Specifically, the wiring region and the non-wiring region can be located in the display area or the non-display area. The thin film transistor and wiring may be provided in the wiring region. The non-wiring region refers to other regions than the wiring region.

The embodiment of the present application contemplates that during the heat dissipation process of the display layer, the heat will be conducted to the metal, i.e., the wiring and the thin film transistor, and the heat has a greater impact on the wiring and the thin film transistor. Therefore, the thickness of the portion of the metal heat conductive layer located in the wiring region is made greater than the thickness of the portion of the metal heat conductive layer located in the non-wiring region, so that the heat in the wiring region can be quickly transferred to the portion of the metal heat conductive layer located in the wiring region, and the heat is conducted to the entire layer of the metal heat conductive layer. The heat is dissipated out through the metal heat conductive layer to improve the heat dissipation effect of the display panel.

In some embodiments, the sum of the thickness of the portion of the metal heat conductive layer located in the non-wiring region and the thickness of the organic layer is greater than the sum of the thickness of the portion of the metal heat conductive layer located in the wiring region.

In some embodiments, the sum of the thickness of the portion of the metal heat conductive layer located in the non-wiring region and the thickness of the organic layer is less than the sum of the thickness of the portion of the metal heat conductive layer located in the wiring region.

In some embodiments, as shown in FIG. 2, the sum of the thickness h1 of the portion of the metal heat conductive layer 21 located in the non-wiring region 282 and the thickness h2 of the organic layer 22 is equal to the sum of the thickness h3 of the portion of the metal heat conductive layer 21 located in the wiring region 281, that is, h1+h2 is equal to h3. By making the sum of the thickness of the portion of the metal heat conductive layer located in the non-wiring region and the thickness of the organic layer equal to the sum of the thickness of the portion of the metal heat conductive layer located in the wiring region, the surface of the organic layer of the metal heat conductive layer close to the buffer layer is rendered flat, which facilitates the preparation of the buffer layer, and the metal heat conductive layer and the organic layer cooperate so that the sum of the thicknesses of the metal heat conductive layer and the organic layer is the thickness of the portion of the metal heat conductive layer located in the wiring region, which can reduce the thickness of the display panel.

Specifically, compared with the case that the sum of the thickness of the portion of the metal heat conductive layer located in the non-wiring region and the thickness of the organic layer is smaller than or greater than the sum of the thicknesses of the portion of the metal heat conductive layer located in the wiring region, the sum of the thickness of the portion of metal heat conductive layer located in the non-wiring region and the thickness of the organic layer is made equal to the sum of the thickness of the portion of the metal heat conductive layer located in the wiring region, such that the sum of the thickness of the metal heat conductive layer and the organic layer is smaller, and the upper surface of the metal heat conductive layer and the organic layer is flat; other film layers can also be kept flat when preparing the other film layers, improving the yield rate of the display panel.

In some embodiments, as shown in FIG. 2, a thin film transistor 247 is provided in the wiring region 281, and the portion of the metal heat conductive layer 21 located in the wiring region 281 covers the wiring region corresponding to the thin film transistor 24. By making the portion of the metal heat conductive layer located in the wiring region cover the wiring region corresponding to the thin film transistor, when heat is transferred to the thin film transistor, the thin film transistor can transfer the heat to the portion of the metal heat conductive layer located in the wiring region, and the metal heat conductive layer transfers the heat to the entire surface and dissipate the heat out through the manner of convection and thermal radiation, improving the heat dissipation effect of the display panel, avoiding the excessive heat of the thin film transistor to result in failure to work normally, and making the display panel have a higher yield rate.

Specifically, as shown in FIG. 2, the thin film transistor 247 is provided in the wiring region 281, and the projection area of the portion of the metal heat conductive layer 21 located in the wiring region 281 on the display layer 25 is greater than or equal to the projection area of the thin film transistor 247 on the display layer 25. By making the projection area of the portion of the metal heat conductive layer located in the wiring region on the display layer greater than or equal to the projection area of the thin film transistor on the display layer, when heat is transferred to the thin film transistor, the thin film transistor can transfer heat to the portion of the metal heat conductive layer located in the wiring region, the metal heat conductive layer conducts the heat to the entire surface and dissipates the heat out through the manner of convection and thermal radiation, improving the heat dissipation effect of the display panel, avoiding the excessive heat of the thin film transistor to result in failure to work normally, and making the display panel have a higher yield rate.

Specifically, the thin film transistor includes a gate, a source, a drain, and an active layer. When the heat is transferred to the thin film transistor, the high temperature may cause the thin film transistor to fail to work normally, or the performance of the thin film transistor may change at the high temperature. By causing the portion of the heat conductive layer located in the wiring region under the thin film transistor and the area of the metal heat conductive layer to be larger than the area of the thin film transistor, the heat of the thin film transistor can be transferred out, and the heat generated by the thin film transistor itself can also be dissipated out through the metal heat conductive layer to improve the heat dissipation effect of the display panel.

In some embodiments, as shown in FIG. 2, the metal wiring 248 is provided in the wiring region 281, and the portion of the metal heat conductive layer 21 located in the wiring region 281 is disposed corresponding to the metal wiring 248, and the portion of the metal heat conductive layer 21 located in the wiring region 281 covers the projection area of the metal wiring 248 on the display layer 25. By making the portion of the metal heat conductive layer located in the wiring region cover the projection area of the metal wiring on the display layer, the heat of the metal wiring can be transferred through the portion of the metal heat conductive layer located in the wiring region, and then dissipated through the entire metal heat conductive layer, improving the heat dissipation effect of the display panel, and avoiding the display panel from failure to display normally caused due to poor heat dissipation of metal wiring.

Specifically, the projection area of the portion of the metal heat conductive layer 21 located in the wiring region 281 on the display layer 25 is greater than or equal to the projection area of the metal wiring 248 on the display layer 25. By making the projection area of the portion of the metal heat conductive layer located in the wiring region on the display layer greater than or equal to the projection area of the metal wiring on the display layer, the heat of the metal wiring can be transferred through the portion of the metal heat conductive layer located in the wiring region, and then dissipated through the entire metal heat conductive layer to improve the heat dissipation effect of the display panel and avoid the failure to display normally caused due to poor heat dissipation of metal wiring.

Specifically, FIG. 2 takes the metal wiring arranged on the source and drain layers as an example for illustration. However, the embodiment of the present application is not limited thereto. The metal wiring may be arranged on other film layers. Correspondingly, the metal wiring includes a scan line, a data line, a power signal line.

In some embodiments, the metal wiring is provided in the wiring region, and the metal wiring is electrically connected to the metal heat conductive layer. By electrically connecting the metal wiring to the metal heat conductive layer, the metal heat conductive layer can function to conduct heat and electricity simultaneously. Correspondingly, the line width of the metal wiring located in other film layers can be reduced, allowing the metal heat conductive layer to function as a portion of the metal wiring, increasing the width of the metal wiring, reducing the impedance of the metal wiring, enlarging the arrangement space for other signal lines, reducing the impedance and voltage drop of the signal line in the display panel, reducing the thermal resistance of the signal line, and improving the heat dissipation capacity of the display panel.

In some embodiments, the metal wiring includes a power signal line, and the metal heat conductive layer is connected to the power signal line. By connecting the metal heat conductive layer to the power signal line, the power signal line can be allowed to input a constant voltage to the metal heat conductive layer, so that the metal heat conductive layer can function to conduct heat and electricity simultaneously. Correspondingly, the line width of the portion of the power signal line located in other film layers can be reduced, allowing the metal heat conductive layer to function as a portion of the power signal line, increasing the width of the power signal line, reducing the impedance of the power signal line, enlarging the arrangement space for other signal lines, reducing the impedance and voltage drop of the signal line in the display panel, reducing the thermal resistance of the signal line and improving the heat dissipation capacity of the display panel.

Specifically, the power supply signal line includes a high potential power supply signal line and a low potential power supply signal line, and the metal heat conductive layer is connected to one of the high potential power supply signal line and the low potential power supply signal line.

In some embodiments, as shown in FIG. 2, the thickness of the portion of the metal heat conductive layer 21 located in the non-wiring region 282 ranges from one-fiftieth to one-fifth of the thickness h3 of the portion of the metal heat conductive layer 21 located in the wiring region 281, which may allow the metal heat conductive layer to be arranged on the entire surface to improve the heat dissipation effect of the display panel, and since the weight of the metal heat conductive layer is smaller, the possibility of generating a static electricity when preparing the buffer layer on the metal heat conductive layer is lower, improving the yield rate of display panel.

Specifically, the thickness of the portion of the metal heat conductive layer located in the non-wiring region ranges from 0.05 microns to 0.1 microns; the thickness of the portion of the metal heat conductive layer located in the wiring region ranges from 0.5 microns to 2.5 microns.

In some embodiments, the material of the metal heat conductive layer includes at least one of copper, aluminium, tin, and molybdenum, thereby improving the heat dissipation effect of the display panel.

TABLE 1
Comparison table of heat conductivity
coefficients of different materials

| | |
|---|---|
| Material | Heat conductivity W/(m × K) |

| | | |
|---|---|---|
| Glass | 23 degrees Celsius | 1.145 |
| | 100 degrees Celsius | 1.183 |
| | 200 degrees Celsius | 1.259 |
| | 300 degrees Celsius | 1.317 |
| | 400 degrees Celsius | 1.351 |
| | 500 degrees Celsius | 1.372 |

| | |
|---|---|
| Copper | 401 |
| Aluminium | 237 |
| Tin | 67 |

As can be seen from Table 1 above, the unit of heat conductivity is W/(m×K), i.e., Watt/(meter×degrees Celsius). At different temperatures, the heat conductivity of glass ranges from 1W/(m×K) to 2(m×K), and the heat conductivity coefficients of copper, aluminium, and tin are 401W/(m×K), 237W/(m×K), and 67W/(m×K) respectively. The heat conductivity of these metals is one to two orders of magnitude larger than that of glass, such that the metal heat conductive layer can conduct heat to the entire surface, increasing the surface area for heat dissipation, instead of concentrating heat in one area like glass, improving the heat dissipation effect.

In some embodiments, as shown in FIG. 2, the display layer 25 includes a micro light-emitting diode device, the micro light-emitting diode device includes an electrode layer 251 and a light-emitting layer 252, and the display panel 2 further includes a bonding pad 29. The electrode layer 251 is disposed between the light-emitting layer 252 and the driving circuit layer 24. The electrode layer 251 is connected to the driving circuit layer 24 through the bonding pad 29. The electrode layer 251 is disposed corresponding to the portion of the heat conductive layer 21 located in the wiring region 281. By disposing the portion of the metal heat conductive layer located in the wiring region corresponding to the electrode layer and the bonding pad, the portion of the metal heat conductive layer located in the wiring region can directly dissipate out the heat generated by the micro light-emitting diode through the electrode layer and the bonding pad, thereby improving the heat dissipation effect of the display panel.

Specifically, FIG. 2 takes the example that the two electrodes of the micro light-emitting diode device are located on the same side of the light-emitting layer for illustration. However, the embodiment of the present application is not limited thereto. The two electrodes of the micro light-emitting diode device may be located on both sides of the light-emitting layer.

In some embodiments, the material of the organic layer includes polyimide. The polyimide is disposed between the buffer layer and the metal heat conductive layer, which can avoid occurrence of the static electricity when forming other film layers on the metal heat conductive layer using chemical vapour deposition, avoid damage of the static electricity to the display panel, and improve the yield rate of the display panel.

In some embodiments, as shown in FIG. 2, the driving circuit layer 24 includes a buffer layer 23, an active layer 241, a gate insulation layer 242, a gate layer 243, an interlayer insulation layer 244, a source/drain layer 245, a passivation layer 246.

In some embodiments, as shown in FIG. 2, the display panel 2 further includes an encapsulation layer 26 and a glass cover plate 27.

The above embodiments respectively describe the display panels of the embodiments of the present application from various aspects. It can be understood that when there is no conflict between each of the embodiments, each of the embodiments can be combined to achieve better technical effect. For example, the thin film transistor and metal wiring are provided in the wiring region. The projection area of the portion of the metal heat conductive layer located in the wiring region on the display layer is greater than or equal to the sum of the projection area of the thin film transistor on the display layer and the projection area of the metal wiring on the display layer. For the structures of other embodiments, please refer to the above description and will not be repeated here.

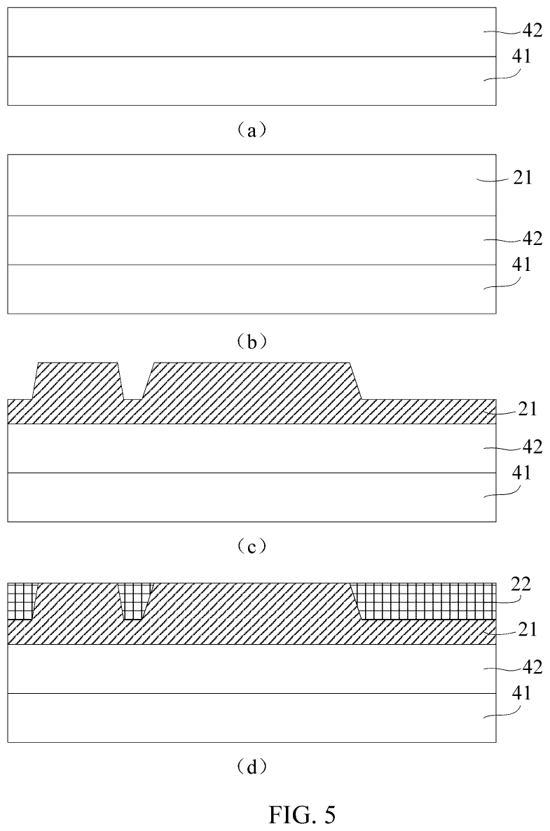

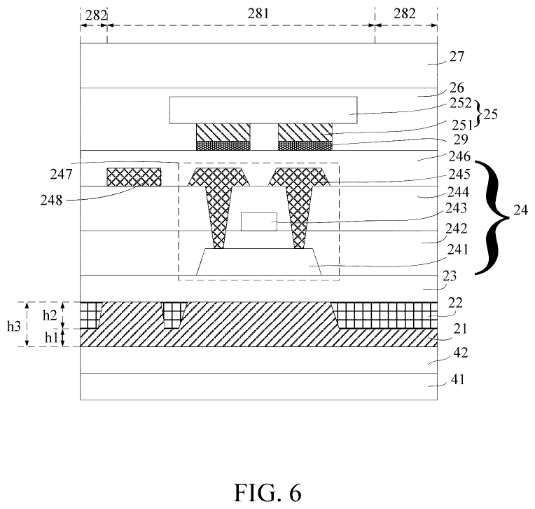

FIG. 5 is a first structural schematic diagram of a display panel corresponding to each step of the preparation method for a display panel provided by an embodiment of the present application. FIG. 6 is a second structural schematic diagram of a display panel corresponding to each step of the preparation method for a display panel provided by an embodiment of the present application.

Meanwhile, embodiments of the present application provide a preparation method for a display panel, the preparation method for a display panel prepares the display panel as described in any one of the above embodiments.

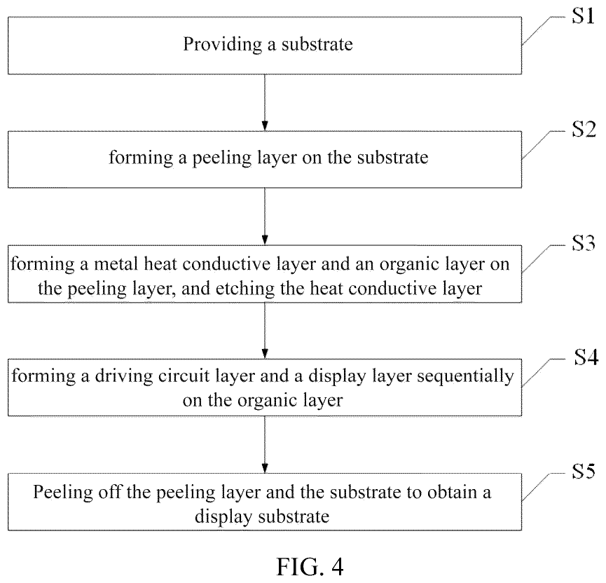

Specifically, as shown in FIG. 4, the display panel prepared by the preparation method for a display panel includes a wiring region and a non-wiring region. The preparation method for the display panel includes:
S1, providing the substrate; the display panel corresponding to this step is shown in (a) in FIG. 5;
S2, forming a peeling layer on the substrate; the display panel corresponding to this step is shown in (a) in FIG. 5;
Specifically, as shown in FIG. 5, a peeling layer 42 may be pasted on the substrate 41. The material of the peeling layer 42 includes a hot melt adhesive agent with polyurethane resin and/or polyamide as the base material.
S3, forming a metal heat conductive layer and an organic layer on the peeling layer, and etching the metal heat conductive layer; the display panel corresponding to this step is as shown in FIG. 5 (b), FIG. 5 (c) and FIG. 5 (c);
S4, form a driving circuit layer and a display layer sequentially on the organic layer; the display panel corresponding to this step is shown in FIG. 6;
S5, peeling off the peeling layer and the substrate to obtain the display panel; the display panel corresponding to this step is shown in FIG. 2.

Embodiments of the present application provide a preparation method for the display panel, by forming a peeling layer on a substrate, forming a metal heat conductive layer, an organic layer, a driving circuit layer and a display layer on the peeling layer, and subsequently peeling off the substrate and the peeling layer, the metal heat conductive layer may be made directly contact the outside world. The metal heat conductive layer conducts the heat out. The metal heat conductive layer has a heat conductivity superior to that of glass, which can improve the heat dissipation effect of the display panel. The metal heat conductive layer can replace the glass substrate without increasing the thickness of the display panel. Meanwhile, in the non-wiring region, the organic layer is provided between the metal heat conductive layer and the driving circuit layer, so that no static electricity will occur when forming the driving circuit layer, improving the yield rate of the display panel.

Specifically, when forming the metal heat conductive layer and the organic layer, as shown in (a) in FIG. 5 to (c) in FIG. 5, the metal heat conductive layer may be provided as the entire surface firstly, and then the metal heat conductive layer is etched, and then the organic layer is formed on the metal heat conductive layer.

Specifically, when forming the metal heat conductive layer and the organic layer, the metal heat conductive layer may be provided as the entire surface firstly, and then the organic layer may be provided on the entire surface, and then a hole is dug in the organic layer, and the metal heat conductive layer is provided in the hole-digging region.

Specifically, the embodiments of the present application use metal as the material of the metal heat conductive layer, so that the metal heat conductive layer and the peeling layer are easier to peel off, avoiding the poor heat dissipation effect of the display panel caused due to failure to peel off the substrate and the peeling layer.

Specifically, the peeling force between the peeling layer and the metal heat conductive layer decreases rapidly at a certain temperature, so that the substrate and the peeling layer can be peeled off, improving the heat dissipation effect of the display panel.

Meanwhile, embodiments of the present application provide a display device, which includes the display panel as described in any of the above embodiments.

According to the above embodiments, it can be known that:

Embodiments of the present application provide a display panel and a preparation method thereof; the display panel has a metal heat conductive layer, an organic layer, a driving circuit layer and a display layer. The organic layer is disposed on a side of the metal heat conductive layer, and the driving circuit layer is disposed on a side of the organic layer away from the metal heat conductive layer. The driving circuit layer includes a thin film transistor and a metal wiring, and the display layer is disposed on a side of the driving circuit layer away from the organic layer. The display panel includes a wiring region and a non-wiring region, and at least one of the thin film transistor and the metal wiring is provided in the wiring region. The metal heat conductive layer includes a connection surface close to and in direct contact with the driving circuit layer, and a heat dissipation surface away from the driving circuit layer. In the orthographic projection direction of the display panel, the orthographic projection area of the heat dissipation surface is greater than the orthographic projection area of the connection surface, and the connection surface is disposed corresponding to the wiring region. In the present application, by arranging a metal heat conductive layer, making the orthogonal projection area of the heat dissipation surface of the metal heat conductive layer away from the driving circuit layer larger than the orthogonal projection area of the connection surface in direct contact with the driving circuit layer, and disposing the connection surface corresponding to the wiring region, the metal heat conductive layer may be made in direct contact with the driving circuit layer in the wiring region, so that when the display panel generates heat, the heat can be conducted out through the metal heat conductive layer, and the metal heat conductive layer has a heat conductivity superior to that of glass, which can improve the heat dissipation effect of the display panel. Moreover, the metal heat conductive layer can replace the glass substrate without increasing the thickness of the display panel. Meanwhile, the heat dissipation surface can conduct the heat to the entire surface, further improving the heat dissipation effect.

In the above embodiments, each embodiment is described with its own emphasis. For those parts that are not described in detail in a certain embodiment, please refer to the relevant descriptions of other embodiments.

The above is a detailed introduction to the display panel and the preparation method thereof provided by the embodiments of the present application. The present disclosure uses specific embodiments to illustrate the principles and implementation methods of the present application. The description of the above embodiments is only used to help understand the technical solutions of the present application and its core idea; meanwhile, one ordinary skill in the art should understand that it is still possible to modify the technical solutions described in each of the aforementioned embodiments, or make equivalent replacements for some of the technical features therein; and these modifications or replacements do not make the essence of the corresponding technical solutions deviate from the scope of the technical solutions of each of the embodiments of the present application.

What is claimed is:

1. A display panel, comprising:
a metal heat conductive layer;
an organic layer, provided on a side of the metal heat conductive layer;
a driving circuit layer, provided on a side of the organic layer away from the metal heat conductive layer, wherein the driving circuit layer comprises a thin film transistor and a metal wiring;
a display layer, provided on a side of the driving circuit layer away from the organic layer, and controllably connected to the driving circuit layer;
wherein the display panel comprises a wiring region and a non-wiring region, and at least one of the thin film transistor and the metal wiring is provided in the wiring region; the metal heat conductive layer comprises a connection surface close to the driving circuit layer and in direct contact with the driving circuit layer, and a heat dissipation surface away from the driving circuit layer, in an orthographic projection direction of the display panel, an orthographic projection area of the heat dissipation surface is larger than an orthographic projection area of the connection surface, and the connection surface is disposed corresponding to the wiring region.

2. The display panel of claim 1, wherein a projection of the metal heat conductive layer on a plane where the display layer is located covers a projection of the driving circuit layer on a plane where the display layer is located.

3. The display panel of claim 1, wherein in a direction perpendicular to the display panel, a thickness of a portion of the metal heat conductive layer located in the wiring region is greater than a thickness of a portion of the metal heat conductive layer located in the non-wiring region, in the non-wiring region, the organic layer is disposed between the metal heat conductive layer and the driving circuit layer.

4. The display panel of claim 3, wherein a sum of the thickness of the portion of the metal heat conductive layer located in the non-wiring region and a thickness of the organic layer is equal to a sum of the thickness of the portion of the metal heat conductive layer located in the wiring region.

5. The display panel of claim 3, wherein the driving circuit layer comprises a buffer layer, the metal heat conductive layer is in direct contact with the buffer layer in the wiring region, and the organic layer is disposed between the metal heat conductive layer and the buffer layer in the non-wiring region.

6. The display panel of claim 1, wherein a thin film transistor is provided in the wiring region, and a portion of the metal heat conductive layer located in the wiring region covers the wiring region corresponding to the thin film transistor.

7. The display panel of claim 6, wherein the thin film transistor comprises a gate electrode, a source, a drain, and an active layer.

8. The display panel of claim 1, wherein a metal wiring is provided in the wiring region, a portion of the metal heat conductive layer located in the wiring region is disposed corresponding to the metal wiring, and the portion of the metal heat conductive layer located in the wiring region covers a projection area of the metal wiring on the display layer.

9. The display panel of claim 1, wherein a metal wiring is provided in the wiring region, and the metal wiring is electrically connected to the metal heat conductive layer.

10. The display panel of claim 9, wherein the metal wiring comprises a power signal line, and the metal heat conductive layer is connected to the power signal line.

11. The display panel of claim 10, wherein the power signal line comprises a high-potential power signal line and a low-potential power signal line, and the metal heat conductive layer is connected to one of the high-potential power signal line and the low-potential power signal line.

12. The display panel of claim 1, wherein a thickness of a portion of the metal heat conductive layer located in the non-wiring region ranges from one-fiftieth to one-fifth of a thickness of a portion of the metal heat conductive layer located in the wiring region.

13. The display panel of claim 1, wherein a thickness of a portion of the metal heat conductive layer located in the non-wiring region ranges from 0.05 microns to 0.1 microns.

14. The display panel of claim 1, wherein a thickness of a portion of the metal heat conductive layer located in the wiring region ranges from 0.5 microns to 2.5 microns.

15. The display panel of claim 1, wherein a material of the metal heat conductive layer comprises at least one of copper, aluminium, or tin.

16. The display panel of claim 1, wherein the display layer comprises a micro light emitting diode device, the micro light emitting diode device comprises an electrode layer and a light emitting layer, the display panel further comprises a bonding pad, the electrode layer is disposed between the light-emitting layer and the driving circuit layer, the electrode layer is connected to the driving circuit layer via the bonding pad, and the bonding pad and a portion of the metal heat conductive located in the wiring region are disposed correspondingly.

17. The display panel of claim 1, wherein a material of the organic layer comprises polyimide.

18. The display panel of claim 1, wherein the driving circuit layer comprises a buffer layer, an active layer, a gate insulating layer, a gate layer, an interlayer insulating layer, a source and drain layer, and a passivation layer.

19. The display panel of claim 1, further comprising an encapsulation layer and a glass cover plate.

20. A preparation method of a display panel, wherein the display panel of claim 1 is prepared by the preparation method of the display panel, and the preparation method of the display panel comprises:
providing a substrate;
forming a peeling layer on the substrate;
forming a metal heat conductive layer and an organic layer on the peeling layer, and etching the metal heat conductive layer;
forming a driving circuit layer and a display layer sequentially on the organic layer;
peeling off the peeling layer and the substrate to obtain the display panel.
